(19) United States
(12) Patent Application Publication
(10) Pub. No.: US 2024/0124955 A1
(43) Pub. Date: Apr. 18, 2024

(54) HOT-ROLLED COPPER ALLOY SHEET AND SPUTTERING TARGET

(71) Applicant: MITSUBISHI MATERIALS CORPORATION, Tokyo (JP)

(72) Inventors: Yosuke NAKASATO, Kitamoto-shi (JP); Kazunari MAKI, Kitamoto-shi (JP); Yasuhiro TSUGAWA, Sakai-shi (JP); U TANI, Sakai-shi (JP)

(73) Assignee: MITSUBISHI MATERIALS CORPORATION, Tokyo (JP)

(21) Appl. No.: 18/547,409

(22) PCT Filed: Feb. 8, 2022
(86) PCT No.: PCT/JP2022/004914

§ 371 Date: Aug. 22, 2023

(30) Foreign Application Priority Data
Mar. 2, 2021 (JP) 2021-032441

(51) Int. Cl. C22C 9/01; B22D 11/00; C22C 1/02; C22C 9/00; C22F 1/08; C23C 14/34; H01J 37/34

(52) U.S. Cl. CPC C22C 9/01; B22D 11/004; C22C 1/02; C22C 9/00; C22F 1/08; C23C 14/3414; H01J 37/3426; H01J 2237/332

(57) ABSTRACT

This hot-rolled copper alloy sheet contains Mg: 0.2 mass % or more and 2.1 mass % or less, Al: 0.4 mass % or more and 5.7 mass % or less, and Ag: 0.01 mass % or less, with a remainder being Cu and inevitable impurities, an area ratio of Cube orientation (area ratio of crystal orientation) measured by an EBSD method is 5% or less, an average KAM value when a boundary between adjacent pixels where an orientation difference between the pixels is 5° or more is regarded as a crystal grain boundary is 2.0 or less, and an average crystal grain size μ in a sheet-thickness central portion is 40 μm or less.

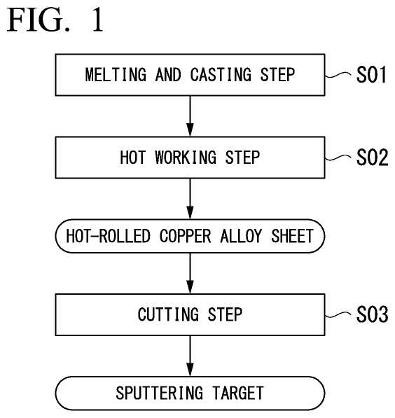

### CROSS-REFERENCE TO RELATED PATENT APPLICATIONS

This application is a U.S. National Phase Application under 35 U.S.C. § 371 of International Patent Application No. PCT/JP2022/004914 filed on Feb. 8, 2022 and claims the benefit of priority to Japanese Patent Application No. 2021-032441 filed on Mar. 2, 2021, the contents of all of which are incorporated herein by reference in their entireties. The International Application was published in Japanese on Sep. 9, 2022 as International Publication No. WO/2022/185859 under PCT Article 21(2).

### FIELD OF THE INVENTION

The present invention relates to a hot-rolled copper alloy sheet suitably used as a hot worked product such as, for example, a sputtering target, a backing plate, an electron tube for an accelerator, or a magnetron, and a sputtering target.

### BACKGROUND OF THE INVENTION

In the related art, as a copper alloy sheet used as the above-described hot worked product, a hot-rolled copper alloy sheet produced by a casting step of producing an ingot of a copper alloy and a hot working step of subjecting the ingot to hot working (hot rolling or hot forging) has been generally used.

For example, Japanese Unexamined Patent Application, First Publication No. 2010-103331 discloses a sputtering target for forming a wiring film for a thin film transistor produced using a hot-rolled copper alloy sheet consisting of a Cu—Mg—Ca-based alloy.

The above-described hot-rolled copper alloy sheet is worked into a product having a desired shape by performing cutting such as milling and drilling and plastic working such as bending. In the above-described copper alloy sheet, it is required to refine the crystal grain size and to reduce the residual strain in order to suppress tears and deformation during working.

As for a hot-rolled copper alloy sheet (sputtering target) according to the related art, only the hot working step was provided as a working process, and thus there was a concern that the refinement of crystal grains and the reduction of residual strain may be insufficient even though conditions of the hot working step were controlled. Therefore, it was not possible to sufficiently suppress tears and deformation during working. In addition, in a case where the above-described hot-rolled copper alloy sheet was used as a sputtering target, it was not possible to sufficiently suppress the occurrence of abnormal discharge in high-output sputtering.

### CITATION LIST

### [Patent Document]

### [Patent Document 1]

Japanese Unexamined Patent Application, First Publication No. 2010-103331

### Technical Problem

The present invention is contrived in view of the above-described circumstances, and an object thereof is to provide a hot-rolled copper alloy sheet which has excellent cuttability and can sufficiently suppress abnormal discharge even in a case where the hot-rolled copper alloy sheet is used as a sputtering target, and a sputtering target.

### SUMMARY OF THE INVENTION

### Solution to Problem

In order to solve the problems, the inventors have conducted intensive studies, and as a result, they found that by optimizing the composition and properly controlling the texture in a hot working step, a metal texture with a fine crystal grain size, a small area ratio of Cube orientation, and a low KAM value is obtained, and thus it is possible to provide a hot-rolled copper alloy sheet having excellent cuttability and to suppress the occurrence of abnormal discharge in high-output sputtering in a case where the hot-rolled copper alloy sheet is used as a sputtering target.

The present invention is contrived based on the above-described findings, and a hot-rolled copper alloy sheet according to one aspect of the present invention contains: 0.2 mass % or more and 2.1 mass % or less of Mg; 0.4 mass % or more and 5.7 mass % or less of Al; and 0.01 mass % or less of Ag, with a remainder being Cu and inevitable impurities, in which a measurement area of 150000 μm² or more is measured at a measurement interval of 1 μm by an EBSD method, measurement results are analyzed by data analysis software OIM to obtain a CI value at each measurement point, measurement points where the CI value is 0.1 or less are removed, an orientation difference between crystal grains is analyzed, an area ratio of Cube orientation (area ratio of crystal orientation) in the measurement region is 5% or less, and an average kernel average misorientation (KAM) value when a boundary between adjacent pixels (measurement points) where an orientation difference between the pixels is 5° or more is regarded as a crystal grain boundary is 2.0 or less, and an average crystal grain size μ in a sheet-thickness central portion is 40 μm or less.

In one aspect of the present invention, the sheet-thickness central portion is a region of 45% to 55% of the total thickness from the surface (interface between the oxide and copper) of the hot-rolled copper alloy sheet in a sheet thickness direction.

According to the hot-rolled copper alloy sheet having the above-described configuration, since the composition is as described above, it is possible to refine the crystal grains by controlling the conditions of the hot working process.

In addition, since the average crystal grain size in the sheet-thickness central portion is 40 μm or less, the area ratio of Cube orientation (area ratio of crystal orientation) is 5% or less, and the average KAM value is 2.0 or less, it is possible to suppress the occurrence of tears during cutting. In addition, when using the hot-rolled copper alloy sheet as a sputtering target, it is possible to suppress the occurrence of abnormal discharge during high-output sputtering.

In the hot-rolled copper alloy sheet according to one aspect of the present invention, a standard deviation σ of crystal grain sizes in the sheet-thickness central portion is preferably 90% or less of the average crystal grain size μ in the sheet-thickness central portion.

In this case, the variation in crystal grain size is small, the crystal grains are uniform and refined, and the occurrence of tears during cutting can be further suppressed. In addition, when using the hot-rolled copper alloy sheet as a sputtering target, it is possible to further suppress the occurrence of abnormal discharge during high-output sputtering.

In addition, in the hot-rolled copper alloy sheet according to one aspect of the present invention, it is preferable that a measurement area of 150000 μm² or more is measured at a measurement interval of 1 μm by an EBSD method, measurement results are analyzed by data analysis software OIM to obtain a CI value at each measurement point, measurement points where the CI value is 0.1 or less are removed, an orientation difference between crystal grains is analyzed by the data analysis software OIM, a boundary between adjacent measurement points where an orientation difference between the measurement points is 15° or more is defined as a grain boundary, and an aspect ratio b/a expressed by a major diameter a and a minor diameter b of the crystal grain size (excluding twin crystals) is 0.3 or more.

In this case, since the aspect ratio b/a expressed by the major diameter a and the minor diameter b of the crystal grain size (excluding twin crystals) is 0.3 or more and a difference between the major diameter a and the minor diameter b is small, the residual strain is small, and it is possible to suppress the occurrence of abnormal discharge when using the hot-rolled copper alloy sheet as a sputtering target.

Furthermore, in the hot-rolled copper alloy sheet according to one aspect of the present invention, it is preferable that a measurement area of 150000 μm² or more is measured at a measurement interval of 1 μm by an EBSD method, measurement results are analyzed by data analysis software OIM to obtain a CI value at each measurement point, measurement points where the CI value is 0.1 or less are removed, an orientation difference between crystal grains is analyzed by the data analysis software OIM, and when a length of a low-angle grain boundary and a subgrain boundary which are boundaries between adjacent measurement points where an orientation difference between the measurement points is 2° or more and 15° or less is represented by L_{LB}, and a length of a high-angle grain boundary which is a boundary between adjacent measurement points where an orientation difference between the measurement points is more than 15° is represented by L_{HB}, L_{LB}/(L_{LB}+L_{HB})<10% is satisfied.

In this case, there are only a few regions where the density of dislocation introduced during working is high, and thus when using the hot-rolled copper alloy sheet as a sputtering target, it is possible to suppress the occurrence of unevenness on the sputtering surface due to the difference in dislocation density, and it is possible to stably deposit a film by sputtering for a long time.

Further, in the hot-rolled copper alloy sheet according to one aspect of the present invention, it is preferable that a Vickers hardness is 120 HV or less.

In this case, the strain amount is reduced, and thus the generation of coarse clusters due to the release of strain during sputtering and the occurrence of unevenness resulting therefrom are reduced. Thus, the occurrence of abnormal discharge is suppressed, and the characteristics as the sputtering target are improved.

Furthermore, in the hot-rolled copper alloy sheet according to one aspect of the present invention, it is preferable that among the inevitable impurities, an amount of Fe is 0.0020 mass % or less, and an amount of S is 0.0030 mass % or less.

In this case, it is possible to suppress the presence of Fe or MgS at grain boundaries, and it is possible to suppress the occurrence of tears during cutting and the occurrence of abnormal discharge during deposition by sputtering due to the inclusions.

A sputtering target according to one aspect of the present invention includes the above-described hot-rolled copper alloy sheet.

According to the sputtering target having the above-described configuration, since the sputtering target includes the above-described hot-rolled copper alloy sheet, it is possible to suppress the occurrence of tears during cutting, and the surface quality is excellent. In addition, it is possible to suppress the occurrence of abnormal discharge during high-output sputtering.

### Advantageous Effects of Invention

According to one aspect of the present invention, it is possible to provide a hot-rolled copper alloy sheet which has excellent cuttability and can sufficiently suppress abnormal discharge even in a case where the hot-rolled copper alloy sheet is used as a sputtering target, and a sputtering target.

### BRIEF DESCRIPTION OF THE DRAWINGS

The FIGURE is a flow diagram of a method of producing a hot-rolled copper alloy sheet (sputtering target) according to the present embodiment.

### DETAILED DESCRIPTION OF THE INVENTION

Hereinafter, a hot-rolled copper alloy sheet according to one embodiment of the present invention will be described.

The hot-rolled copper alloy sheet according to the present embodiment is used as a hot worked product such as a sputtering target, a backing plate, an electron tube for an accelerator, or a magnetron, and in the present embodiment, the hot-rolled copper alloy sheet is used as a sputtering target for depositing a copper alloy thin film for wiring.

The hot-rolled copper alloy sheet according to the present embodiment has a composition containing Mg in an amount of 0.2 mass % or more and 2.1 mass % or less, Al in an amount of 0.4 mass % or more and 5.7 mass % or less, and Ag in an amount of 0.01 mass % or less, with a remainder of Cu and inevitable impurities.

In the present embodiment, among the above-described inevitable impurities, an amount of Fe is preferably 0.0020 mass % or less, and an amount of S is preferably 0.0030 mass % or less.

In addition, in the hot-rolled copper alloy sheet according to the present embodiment, a measurement area of 150000 μm² or more is measured at a measurement interval of 1 μm by an EBSD method, and the measurement results are analyzed by data analysis software OIM to obtain a CI value at each measurement point. The measurement points where the CI value is 0.1 or less are removed, and an orientation difference between crystal grains is analyzed. An area ratio of Cube orientation (area ratio of crystal orientation) in the measurement region is 5% or less. Further, an average KAM value when a boundary between adjacent pixels (measurement points) where an orientation difference between the pixels is 5° or more is regarded as a crystal grain boundary is 2.0 or less.

In addition, in the hot-rolled copper alloy sheet according to the present embodiment, an average crystal grain size μ in a sheet-thickness central portion is 40 μm or less.

Furthermore, in the hot-rolled copper alloy sheet according to the present embodiment, a standard deviation σ of the crystal grain sizes in the sheet-thickness central portion is preferably 90% or less of the average crystal grain size μ in the sheet-thickness central portion.

In addition, in the hot-rolled copper alloy sheet according to the present embodiment, a measurement area of 150000 μm² or more is measured at a measurement interval of 1 μm by an EBSD method, and the measurement results are analyzed by data analysis software OIM to obtain a CI value at each measurement point. The measurement points where the CI value is 0.1 or less are removed, and an orientation difference between crystal grains is analyzed by the data analysis software OIM. A boundary between adjacent measurement points where the orientation difference between the measurement points is 15° or more is defined as a grain boundary. An aspect ratio b/a expressed by a major diameter a and a minor diameter b of the crystal grain size (excluding twin crystals) is preferably 0.3 or more.

Furthermore, in the hot-rolled copper alloy sheet according to the present embodiment, a measurement area of 150000 μm² or more is measured at a measurement interval of 1 μm by an EBSD method, and the measurement results are analyzed by data analysis software OIM to obtain a CI value at each measurement point. The measurement points where the CI value is 0.1 or less are removed, and an orientation difference between crystal grains is analyzed by the data analysis software OIM. A length of a low-angle grain boundary and a subgrain boundary which are boundaries between adjacent measurement points where the orientation difference between the measurement points is 2° or more and 15° or less is represented by L_{LB}, and a length of a high-angle grain boundary which is a boundary between adjacent measurement points where the orientation difference between the measurement points is more than 15° is represented by L_{HB}. In this case, L_{LB}/(L_{LB}+L_{HB})<10% is preferably satisfied.

In addition, in the hot-rolled copper alloy sheet according to the present embodiment, Vickers hardness is preferably 120 HV or less.

In the hot-rolled copper alloy sheet according to the present embodiment, the reasons for specifying the component composition, the texture, and the characteristics as described above will be described.

(Mg)

Mg has an effect of refining the crystal grain size of the hot-rolled copper alloy sheet. In addition, Mg improves migration resistance by suppressing the occurrence of thermal defects such as hillocks and voids in a copper alloy thin film constituting a wiring film of a thin film transistor. Furthermore, Mg forms an oxide layer containing Mg on a front surface and a rear surface of the copper alloy thin film during a heat treatment; and thereby, Si or the like as a main component of a glass substrate and a Si film is prevented from diffusing and permeating into the copper alloy wiring film. Accordingly, Mg prevents an increase in specific resistance of the copper alloy wiring film. In addition, Mg acts to improve the adhesion of the copper alloy wiring film to the glass substrate and the Si film. In order to describe the action of Mg in more detail, the oxide layer containing Mg has both the following two effects.

(1) In a case where Si permeates into the copper alloy wiring film, there is a concern that dielectric breakdown may occur. The oxide layer containing Mg serves as a barrier layer.

(2) The adhesion between Cu and the glass substrate is not good. The oxide layer containing Mg acts to improve the adhesion between the copper alloy wiring film and the glass substrate.

In a case where an amount of Mg is less than 0.2 mass %, there is a concern that the above-described effects may not be achieved. Meanwhile, in a case where the amount of Mg is more than 2.1 mass %, the specific resistance value increases and the wiring film does not exhibit sufficient functions. Therefore, the amount of Mg of more than 2.1 mass % is not preferable.

Therefore, in the present embodiment, the amount of Mg is in a range of 0.2 mass % or more and 2.1 mass % or less.

In order to further exhibit the above-described effects, the lower limit of the amount of Mg is more preferably 0.3 mass % or more, and even more preferably 0.4 mass % or more. Meanwhile, in order to further suppress an increase in specific resistance value, the upper limit of the amount of Mg is more preferably 1.5 mass % or less, and even more preferably 1.2 mass % or less.

(Al)

Al has an effect of improving the adhesion and chemical stability of a deposited copper alloy thin film when being contained together with Mg. That is, in a copper alloy thin film deposited using a sputtering target containing Al and Mg together, a multiple oxide or oxide solid solution of Mg, Cu, and Al is formed on a surface of the copper alloy thin film by a heat treatment, and thus adhesion and chemical stability are improved.

In a case where an amount of Al of the hot-rolled copper alloy sheet is less than 0.4 mass %, there is a concern that the above-described effects may not be achieved. Furthermore, depending on conditions of hot working, Cube-oriented crystal grains of the hot-rolled copper alloy sheet tend to become coarse. In a case where coarse crystal grains are present, tears during cutting and abnormal discharge during sputtering are likely to occur. Meanwhile, in a case where the amount of Al of the hot-rolled copper alloy sheet is more than 5.7 mass %, the specific resistance value increases and the wiring film does not exhibit sufficient functions. Therefore, the amount of Al of more than 5.7 mass % is not preferable.

Therefore, in the present embodiment, the amount of Al is in a range of 0.4 mass % or more and 5.7 mass % or less.

In order to further exhibit the above-described effects, the lower limit of the amount of Al is more preferably 0.6 mass % or more, and even more preferably 0.9 mass % or more. Meanwhile, in order to further suppress an increase in specific resistance value, the upper limit of the amount of Al is more preferably 5.0 mass % or less, and even more preferably 4.2 mass % or less.

(Ag)

Ag is concentrated in the crystal grain boundaries of a copper alloy, and has an effect of suppressing the grain growth, the occurrence of tears during cutting, and the occurrence of abnormal discharge during deposition by sputtering. In a case where an amount of Ag is more than 0.01 mass %, the above-described effects are not improved, and the production cost increases.

Therefore, in the present embodiment, the amount of Ag is specified to be 0.01 mass % or less.

In order to further reduce the production cost, the upper limit of the amount of Ag is more preferably 0.005 mass % or less, and even more preferably 0.002 mass % or less. In addition, the lower limit of the amount of Ag is not particularly limited, but in order to securely exhibit the above-described effects, the lower limit of the amount of Ag is more preferably 0.0001 mass % or more, and even more preferably 0.0003 mass % or more.

(Fe, S)

In a case where Fe and S are contained in large amounts among the inevitable impurities, Fe or MgS is present in grain boundaries, and due to the inclusions, there is a concern that tears during cutting and abnormal discharge during sputtering may occur.

Therefore, in the present embodiment, an amount of Fe is preferably 0.0020 mass % or less, and an amount of S is preferably 0.0030 mass % or less.

The upper limit of the amount of Fe is more preferably 0.0015 mass % or less, and even more preferably 0.0010 mass % or less. The upper limit of the amount of S is more preferably 0.0020 mass % or less, and even more preferably 0.0015 mass % or less.

(Other Inevitable Impurities)

Examples of other inevitable impurities other than the above-described elements include As, B, Ba, Be, Bi, Ca, Cd, Cr, Sc, rare earth elements, V, Nb, Ta, Mo, Ni, W, Mn, Re, Ru, Sr, Ti, Os, Co, Rh, Ir, Pb, Pd, Pt, Au, Zn, Zr, Hf, Hg, Ga, In, Ge, Y, Tl, N, Sb, Se, Si, Sn, Te, Li, O, and P. These inevitable impurities may be contained within a range not to affect the characteristics.

Since there is a concern that these inevitable impurities may increase inclusions, which cause tears during cutting and abnormal discharge during sputtering, an amount of the inevitable impurities is preferably reduced.

(Area Ratio of Cube Orientation)

In the hot-rolled copper alloy sheet, Cube-oriented crystal grains tend to become coarse depending on conditions of hot working. Therefore, in a case where the area ratio of Cube orientation is high, coarse crystal grains are present, and thus tears during cutting and abnormal discharge during sputtering are likely to occur.

Therefore, in the present embodiment, the area ratio of Cube orientation is specified to be 5% or less.

The upper limit of the area ratio of Cube orientation is preferably 4% or less, and more preferably 3% or less. In addition, the lower limit of the area ratio of Cube orientation is not particularly limited.

(KAM Value)

The kernel average misorientation (KAM) value measured by an EBSD method is a value calculated by averaging the orientation differences between one pixel and pixels surrounding the pixel. Since the shape of the pixel is a regular hexagon, in a case where the degree of proximity is set to 1 (1st), an average of the orientation differences between one pixel and six adjacent pixels is calculated as the KAM value. In the present embodiment, regions where the CI value, which indicates the clarity of the crystallinity of an analysis point, is 0.1 or less, a worked texture has significantly developed and a clear crystal pattern cannot be obtained are excluded, and an average of the KAM values is obtained in the texture excluding the regions.

By using the KAM value, it is possible to visualize the local orientation difference, that is, the strain distribution. Since a region with a high KAM value is a region where high strain has been introduced during working, the sputtering efficiency thereof is different from that of other regions. Accordingly, as the sputtering progresses, unevenness due to the level of the strain is likely to occur and abnormal discharge is likely to occur.

Therefore, in the present embodiment, the average KAM value is 2.0 or less.

The upper limit of the average KAM value is preferably 1.8 or less, and more preferably 1.5 or less. In addition, the lower limit of the average KAM value is not particularly limited.

(Average Crystal Grain Size in Sheet-Thickness Central Portion)

In the hot-rolled copper alloy sheet according to the present embodiment, in a case where the average crystal grain size in the sheet-thickness central portion (a region of 45% to 55% of the total thickness from the surface (interface between the oxide and copper) of the hot-rolled copper alloy sheet in the sheet thickness direction) is fine, fine tears are less likely to occur on the surface during cutting. In addition, when using the hot-rolled copper alloy sheet as a sputtering target, the unevenness during sputtering is fine in a case where the crystal grain size is fine. Accordingly, abnormal discharge is suppressed, and sputtering characteristics are improved.

Therefore, in the hot-rolled copper alloy sheet according to the present embodiment, the average crystal grain size μ in the sheet-thickness central portion is specified to be 40 μm or less.

The upper limit of the average crystal grain size μ in the sheet-thickness central portion is preferably 30 μm or less, and more preferably 25 μm or less. In addition, the lower limit of the average crystal grain size μ in the sheet-thickness central portion is not particularly limited.

(Standard Deviation of Crystal Grain Sizes in Sheet-Thickness Central Portion)

In the hot-rolled copper alloy sheet according to the present embodiment, in a case where the standard deviation σ of the crystal grain sizes in the sheet-thickness central portion is sufficiently small, the variation in crystal grain size is reduced. Accordingly, when using the hot-rolled copper alloy sheet as a sputtering target, the unevenness of every crystal grain due to sputtering is uniform, and thus it is possible to further suppress the occurrence of abnormal discharge.

Therefore, in the hot-rolled copper alloy sheet according to the present embodiment, the standard deviation σ of the crystal grain sizes in the sheet-thickness central portion is preferably set to 90% or less of the average crystal grain size u in the sheet-thickness central portion.

The upper limit of the standard deviation σ of the crystal grain sizes in the sheet-thickness central portion is more preferably 80% or less, and even more preferably 70% or less of the average crystal grain size μ in the sheet-thickness central portion. In addition, the lower limit of the standard deviation σ of the crystal grain sizes in the sheet-thickness central portion is not particularly limited.

(Aspect Ratio)

When the major diameter of the crystal grain size is represented by a and the minor diameter thereof is represented by b, the aspect ratio represented by b/a is an index indicating the degree of working of the material, and abnormal discharge during sputtering tends to increase as the aspect ratio decreases (that is, as the difference between the major diameter a and the minor diameter b increases).

Therefore, in the hot-rolled copper alloy sheet according to the present embodiment, when the major diameter of the crystal grain size is represented by a and the minor diameter thereof is represented by b, the aspect ratio represented by b/a is preferably 0.3 or more. The aspect ratio b/a of the crystal grains in the hot-rolled copper alloy sheet is an average of measured aspect ratios of a plurality of crystal grains.

The lower limit of the aspect ratio b/a is more preferably 0.4 or more, and even more preferably 0.5 or more. In addition, the upper limit of the aspect ratio b/a is not particularly limited.

(Ratio of Length of Low-Angle Grain Boundary and Subgrain Boundary)

Since a low-angle grain boundary and a subgrain boundary are regions where the density of dislocation introduced during working is locally high, the sputtering efficiency thereof is different from that of other regions. Accordingly, as the sputtering progresses, unevenness due to the level of the strain tends to occur and abnormal discharge tends to easily occur.

Therefore, in the hot-rolled copper alloy sheet according to the present embodiment, when a length of a low-angle grain boundary and a subgrain boundary is represented by L_{LB}, and a length of a high-angle grain boundary is represented by L_{HB}, L_{LB}/(L_{LB}+L_{HB})<10% is preferably satisfied.

The low-angle grain boundary and the subgrain boundary are boundaries between adjacent measurement points where the orientation difference between the measurement points is 2° or more and 15° or less. The high-angle grain boundary is a boundary between adjacent measurement points where the orientation difference between the measurement points is more than 15°.

The upper limit of L_{LB}/(L_{LB}+L_{HB}) is more preferably less than 8%, and even more preferably less than 6%. In addition, the lower limit of L_{LB}/(L_{LB}+L_{HB}) is not particularly limited.

(Vickers Hardness)

In a case where the hot-rolled copper alloy sheet has a high Vickers hardness, a residual strain amount is large and coarse clusters are generated due to the release of strain during sputtering and unevenness resulting therefrom occurs. Thus, there is a concern that abnormal discharge may be likely to occur.

Therefore, in the hot-rolled copper alloy sheet according to the present embodiment, the Vickers hardness is preferably 120 HV or less.

The upper limit of the Vickers hardness is more preferably 110 HV or less, and even more preferably 100 HV or less. In addition, the lower limit of the Vickers hardness is not particularly limited, but is more preferably 50 HV or more, and even more preferably 70 HV or more.

Next, a method of producing the hot-rolled copper alloy sheet according to the present embodiment (a method of producing a sputtering target) which has the above-described configuration will be described with reference to the flow diagram shown in the FIGURE.

(Melting and Casting Step S01)

First, the above-described elements are added to molten copper obtained by melting a copper raw material to adjust components, and thus a molten copper alloy is produced. Further, a single element, a master alloy, or the like can be used for addition of various elements. In addition, raw materials containing the above-described elements may be melted together with the copper raw material. Further, a recycled material or a scrap material of the alloy of the embodiment may be used.

As the copper raw material, so-called 4 NCu having a purity of 99.99 mass % or more or so-called 5 NCu having a purity of 99.999 mass % or more is preferably used.

In order to suppress oxidation of Mg and to reduce the hydrogen concentration during melting, it is preferable that the melting is carried out in an atmosphere using an inert gas atmosphere (for example, Ar gas) in which the vapor pressure of H₂O is low and the holding time for the melting is set to the minimum.

Further, the molten copper alloy in which the components have been adjusted is poured into a mold to produce a copper alloy ingot. In consideration of mass production, a continuous casting method or a semi-continuous casting method is preferably used.

(Hot Working Step S02)

Next, the obtained copper alloy ingot is subjected to hot working. In the present embodiment, hot rolling is performed to obtain a hot-rolled copper alloy sheet according to the present embodiment.

The rolling ratio in each pass in the hot rolling step is 50% or less, and the total rolling ratio in the rolling is 98% or less. Regarding final four passes, in a case where the rolling ratio in each pass is less than 4%, the area ratio of Cube orientation is high and the crystal grains become coarse. In a case where the rolling ratio in each pass is more than 45%, the KAM value is high and the aspect ratio decreases. Therefore, the rolling ratio in each of the final four passes is 4% to 45%. Furthermore, regarding the final four passes, in order to reduce the KAM value and to increase the aspect ratio, the rolling ratio in each pass is preferably reduced as the passes progress.

The “final four passes” refer to four passes that are performed at the end of the multi-pass hot rolling step. For example, in a case where ten passes are performed during hot rolling, final four passes mean the 7-th pass, the 8-th pass, the 9-th pass, and the 10-th pass.

In addition, in a case where the starting temperature before the final four passes in the hot rolling step described above is 600° C. or lower, the KAM value increases, and in a case where the starting temperature before the final four passes is 850° C. or higher, the crystal grains become coarse. In addition, in a case where the end temperature after the final four passes is 550° C. or lower, the KAM value increases, and in a case where the end temperature after the final four passes is 800° C. or higher, the crystal grains become coarse.

Therefore, in the present embodiment, the starting temperature before the final four passes is preferably higher than 600° C. and lower than 850° C. In addition, the end temperature after the final four passes is preferably higher than 550° C. and lower than 800° C.

Furthermore, in a case where the cooling rate from the end of hot rolling to a temperature of 200° C. or lower is smaller than 200° C./min, the crystal grains in the sheet-thickness central portion become coarse, and there is a concern that the variation in crystal grain size may increase.

Therefore, in the present embodiment, the cooling rate from the end of hot rolling to a temperature of 200° C. or lower is preferably 200° C./min or more.

After finish hot rolling, in order to adjust the shape of the hot-rolled copper alloy sheet, cold rolling with a rolling ratio of 10% or less or shape correction with a leveler may be performed.

(Cutting Step S03)

A sputtering target is produced by cutting the obtained hot-rolled copper alloy sheet according to the present embodiment.

The hot-rolled copper alloy sheet according to the present embodiment which has the above-described configuration has a composition containing 0.2 mass % or more and 2.1 mass % or less of Mg, 0.4 mass % or more and 5.7 mass % or less of Al, and 0.01 mass % or less of Ag, with a remainder of Cu and inevitable impurities. Therefore, by controlling the conditions of the hot working process, it is possible to refine the crystal grains.

In addition, in the hot-rolled copper alloy sheet according to the present embodiment, the average crystal grain size μ in the sheet-thickness central portion is 40 μm or less, the area ratio of Cube orientation (area ratio of crystal orientation) is 5% or less, and the average KAM value is 2.0 or less. Therefore, it is possible to suppress the occurrence of tears during cutting. In addition, when using the hot-rolled copper alloy sheet as a sputtering target, it is possible to suppress the occurrence of abnormal discharge during high-output sputtering.

In addition, in the present embodiment, in a case where the standard deviation σ of the crystal grain sizes in the sheet-thickness central portion is 90% or less of the average crystal grain size μ in the sheet-thickness central portion, the variation in crystal grain size is small, and thus the crystal grains are uniform and refined. Therefore, it is possible to further suppress the occurrence of tears during cutting. In addition, when using the hot-rolled copper alloy sheet as a sputtering target, it is possible to further suppress the occurrence of abnormal discharge during sputtering.

In addition, in the present embodiment, a measurement area of 150000 μm² or more is measured at a measurement interval of 1 μm by an EBSD method, and the measurement results are analyzed by data analysis software OIM to obtain a CI value at each measurement point. The measurement points where the CI value is 0.1 or less are removed, and an orientation difference between crystal grains is analyzed by the data analysis software OIM. A boundary between adjacent measurement points where the orientation difference between the measurement points is 15° or more is defined as a grain boundary. In a case where an aspect ratio b/a expressed by a major diameter a and a minor diameter b of the crystal grain size (excluding twin crystals) is 0.3 or more, the residual strain is small, and it is possible to suppress the occurrence of abnormal discharge when using the hot-rolled copper alloy sheet as a sputtering target.

Furthermore, in the present embodiment, a measurement area of 150000 μm² or more is measured at a measurement interval of 1 μm by an EBSD method, and the measurement results are analyzed by data analysis software OIM to obtain a CI value at each measurement point. The measurement points where the CI value is 0.1 or less are removed, and an orientation difference between crystal grains is analyzed by the data analysis software OIM. A length of a low-angle grain boundary and a subgrain boundary which are boundaries between adjacent measurement points where the orientation difference between the measurement points is 2° or more and 15° or less is represented by L_{LB}, and a length of a high-angle grain boundary which is a boundary between adjacent measurement points where the orientation difference between the measurement points is more than 15° is represented by L_{HB}. In this case, in a case where L_{LB}/(L_{LB}+L_{HB})<10% is satisfied, there are only a few regions where the density of dislocation introduced during working is high, and thus when using the hot-rolled copper alloy sheet as a sputtering target, it is possible to suppress the occurrence of unevenness on the sputtering surface due to the difference in dislocation density, it is possible to suppress the occurrence of abnormal discharge during sputtering, and it is possible to stably deposit a film by sputtering for a long time.

In addition, in the present embodiment, in a case where the Vickers hardness is 120 HV or less, a strain amount is reduced; and thereby, the generation of coarse clusters due to the release of strain during sputtering and the occurrence of unevenness resulting therefrom are reduced. Thus, the occurrence of abnormal discharge is suppressed, and the characteristics as the sputtering target are improved.

Furthermore, in the present embodiment, in a case where an amount of Fe is 0.0020 mass % or less and an amount of S is 0.0030 mass % or less among the inevitable impurities, it is possible to suppress the presence of Fe or MgS in grain boundaries, and it is possible to suppress the occurrence of tears during cutting and the occurrence of abnormal discharge during deposition by sputtering due to the inclusions.

The hot-rolled copper alloy sheet according to the present embodiment has been described, but the present invention is not limited thereto and can be appropriately modified without departing from the technical requirements of the present invention.

For example, in the above-described embodiment, an example of the method of producing the hot-rolled copper alloy sheet has been described, but the method of producing the copper alloy is not limited to the producing method described in the embodiment, and a producing method of the related art may be appropriately selected for production.

### EXAMPLES

Hereinafter, results of confirmation experiments performed to confirm the effects of the present invention will be described.

### Invention Examples

Oxygen-free copper (99.99 mass % or more) was melted in an Ar gas atmosphere by a heating furnace. Mg, Al, and Ag were added to the obtained molten metal to produce a copper alloy ingot using a continuous casting machine. The dimensions of the material before rolling were width: 600 mm×length: 900 mm×thickness: 240 mm, and a rolling step was performed under conditions shown in Table 2 to produce a hot-rolled copper alloy sheet.

A rolling ratio in each pass in the hot rolling step was 50% or less, and a total rolling ratio in the hot rolling was 98% or less. A rolling ratio in each of final four passes was 4% to 45%. In addition, a starting temperature before the final four passes and an end temperature after the final four passes in the above-described hot rolling step are shown in Table 2. The temperature was measured by measuring a surface temperature of the rolled sheet using a radiation thermometer.

After this hot rolling was ended, the rolled sheet was cooled by water cooling at a cooling rate of 200° C./min or more until the temperature reached 200° C. or lower.

### Comparative Examples

Oxygen-free copper (99.99 mass % or more) was melted in an Ar gas atmosphere by a heating furnace. Mg, Al, and Ag were added to the obtained molten metal to produce a copper alloy ingot using a continuous casting machine. The dimensions of the material before rolling were width: 600 mm×length: 900 mm×thickness: 240 mm, and a rolling step was performed under conditions shown in Table 2 to produce a hot-rolled copper alloy sheet.

A rolling ratio in each pass in the hot rolling step was 50% or less, and a total rolling ratio in the hot rolling was 98%. In addition, a starting temperature before the final four passes and an end temperature after the final four passes in the above-described hot rolling step are shown in Table 2. The temperature was measured by measuring a surface temperature of the rolled sheet using a radiation thermometer. After this hot rolling was ended, the rolled sheet was cooled by water cooling or air cooling until the temperature reached 200° C. or lower.

With respect to the hot-rolled copper alloy sheets of Invention Examples 1 to 17 and Comparative Examples 1 to 8 obtained as described above, an area ratio of Cube orientation, an average crystal grain size, a standard deviation of the crystal grain sizes, an average KAM value, an aspect ratio, a ratio of a length of a low-angle grain boundary and a subgrain boundary, and a Vickers hardness were measured. In addition, the state of tears during milling task and the number of times of abnormal discharge in a case where the hot-rolled copper alloy sheet was used as a sputtering target were evaluated.

(Composition Analysis)

A measurement specimen was collected from the obtained ingot, and the amounts of Mg and Al were measured by an inductively coupled plasma optical emission spectrometry. The amounts of Ag and Fe were measured by inductively coupled plasma mass spectrometry. The amount of S was measured by a combustion-infrared absorption method. Further, the measurement was performed at two sites, the central portion of the specimen and the end portion of the specimen in the width direction, and the larger amount was defined as the amount of the sample. As a result, it was confirmed that the component compositions were as shown in Table 1. Fe and S in Table 1 were inevitable impurities.

(Area Ratio of Cube Orientation)

A sheet-thickness central portion in a surface perpendicular to the width direction of rolling of the hot-rolled copper alloy sheet, that is, a transverse-direction (TD) surface was subjected to machine polishing by using waterproof abrasive paper and diamond abrasive grains on. Next, finish polishing was performed using a colloidal silica solution. Then, the observation surface was measured in a measurement area of 150000 μm² or more at a measurement interval of 1 μm and at an electron beam acceleration voltage of 15 kV by an EBSD method using an EBSD measuring device (Quanta FEG 450, manufactured by FEI, and OIM Data Collection, manufactured by EDAX/TSL (currently AMETEK)) and analysis software (OIM Data Analysis ver. 7.3.1, manufactured by EDAX/TSL (currently AMETEK)). The measurement results were analyzed by the data analysis software OIM to obtain a confidence index (CI) value at each measurement point. The measurement points where the CI value was 0.1 or less were removed, and the orientation difference between crystal grains was analyzed by the data analysis software OIM. The area ratio of crystal grains having an orientation difference of 10° or less from the Cube orientation ({001}<100>) was defined as an area ratio of Cube orientation.

(Average KAM Value)

A sheet-thickness central portion in a surface perpendicular to the width direction of rolling of the obtained hot-rolled copper alloy sheet, that is, a transverse-direction (TD) surface was subjected to machine polishing by using waterproof abrasive paper and diamond abrasive grains. Next, finish polishing was performed using a colloidal silica solution. Then, the observation surface was measured in a measurement area of 150000 μm² or more at a measurement interval of 1 μm and at an electron beam acceleration voltage of 15 kV by an EBSD method using an EBSD measuring device (Quanta FEG 450, manufactured by FEI, and OIM Data Collection, manufactured by EDAX/TSL (currently AMETEK)) and analysis software (OIM Data Analysis ver. 7.3.1, manufactured by EDAX/TSL (currently AMETEK)). The measurement results were analyzed by the data analysis software OIM to obtain a CI value at each measurement point. The measurement points where the CI value was 0.1 or less were removed, and the orientation difference between crystal grains was analyzed by the data analysis software OIM. KAM values of all the pixels analyzed by regarding a boundary between adjacent pixels where the orientation difference between the pixels was 5° or more as a crystal grain boundary were obtained, and an average thereof was obtained.

(Average Crystal Grain Size)

An average crystal grain size and a standard deviation were calculated in a sheet-thickness central portion of a surface perpendicular to the width direction of rolling of the obtained hot-rolled copper alloy sheet, that is, a transverse-direction (TD) surface. For each specimen, a surface perpendicular to the width direction of rolling of the copper alloy sheet, that is, a transverse-direction (TD) surface was subjected to machine polishing by using waterproof abrasive paper and diamond abrasive grains. Next, finish polishing was performed using a colloidal silica solution. Then, the observation surface was measured in a measurement area of 150000 μm² or more at a measurement interval of 1 μm and at an electron beam acceleration voltage of 15 kV by an EBSD method using an EBSD measuring device (Quanta FEG 450, manufactured by FEI, and OIM Data Collection, manufactured by EDAX/TSL (currently AMETEK)) and analysis software (OIM Data Analysis ver. 7.3.1, manufactured by EDAX/TSL). The measurement results were analyzed by the data analysis software OIM to obtain a CI value at each measurement point. The measurement points where the CI value was 0.1 or less were removed, and the orientation difference between crystal grains was analyzed by the data analysis software OIM. A boundary between adjacent measurement points where the orientation difference between the measurement points was 15° or more was defined as a crystal grain boundary, and using the data analysis software OIM, an average crystal grain size μ and a standard deviation σ were obtained by the area fraction, that is, the area ratio.

(Aspect Ratio)

A sheet-thickness central portion in a surface perpendicular to the width direction of rolling of the obtained hot-rolled copper alloy sheet, that is, a transverse-direction (TD) surface was subjected to machine polishing by using waterproof abrasive paper and diamond abrasive grains on. Next, finish polishing was performed using a colloidal silica solution. Then, the observation surface was measured in a measurement area of 150000 μm² or more at a measurement interval of 1 μm and at an electron beam acceleration voltage of 15 kV by an EBSD method using an EBSD measuring device (Quanta FEG 450, manufactured by FBI, and OIM Data Collection, manufactured by EDAX/TSL (currently AMETEK)) and analysis software (OIM Data Analysis ver. 7.3.1, manufactured by EDAX/TSL (currently AMETEK)). The measurement results were analyzed by the data analysis software OIM to obtain a CI value at each measurement point. The measurement points where the CI value was 0.1 or less were removed, and the orientation difference between crystal grains (excluding twin crystals) was analyzed by the data analysis software OIM. A boundary between adjacent measurement points where the orientation difference between the measurement points was 15° or more was defined as a grain boundary, and an aspect ratio represented by b/a was measured when a major diameter of the crystal grain size of each crystal grain was represented by a and a minor diameter thereof was represented by b. An average of the measured aspect ratios of the crystal grains was calculated and defined as the aspect ratio of the specimen. In addition, in the measurement of the aspect ratio, as a grain size by the EBSD, a grain tolerance angle was set to 5° and a minimum grain size was set to 2 pixels for measurement. In a case where the orientation difference between adjacent measurement points was an angle difference of the grain tolerance angle or more, the boundary between the adjacent measurement points was regarded as a grain boundary. Therefore, in a case where the grain tolerance angle was set to 5° in the data analysis software OIM and the orientation difference between adjacent measurement points was 5° or more, the crystal grain size was measured by regarding these measurement points as different crystal grains and regarding the boundary between these adjacent measurement points as a grain boundary.

(Ratio of Length of Low-Angle Grain Boundary and Subgrain Boundary)

A sheet-thickness central portion in a surface perpendicular to the width direction of rolling of the obtained hot-rolled copper alloy sheet, that is, a transverse-direction (TD) surface was subjected to machine polishing by waterproof abrasive paper and diamond abrasive grains. Next, finish polishing was performed using a colloidal silica solution. Then, the observation surface was measured in a measurement area of 150000 μm² or more at a measurement interval of 1 μm and at an electron beam acceleration voltage of 15 kV by an EBSD method using an EBSD measuring device (Quanta FEG 450, manufactured by FEI, and OIM Data Collection, manufactured by EDAX/TSL (currently AMETEK)) and analysis software (OIM Data Analysis ver. 7.3.1, manufactured by EDAX/TSL (currently AMETEK)). The measurement results were analyzed by the data analysis software OIM to obtain a CI value at each measurement point. The measurement points where the CI value was 0.1 or less were removed, and the orientation difference between crystal grains was analyzed by the data analysis software OIM. A boundary between adjacent measurement points where the orientation difference between the measurement points was 15° or more was defined as a crystal grain boundary, and an average grain size A was obtained by the area fraction. Thereafter, the observation surface was measured at a measurement interval which was 1/10 or less of the average grain size A by the EBSD method. The measurement results were analyzed by the data analysis software OIM with a measurement area where the total area of a plurality of visual fields was 150000 μm² or more such that a total of 1000 or more crystal grains were included, to obtain a CI value at each measurement point. The measurement points where the CI value was 0.1 or less were removed, and the orientation difference between crystal grains was analyzed by the data analysis software OIM. A boundary between adjacent measurement points where the orientation difference between the measurement points was 2° or more and 15° or less was defined as a low-angle grain boundary and a subgrain boundary, and a length thereof was represented by L_{LB}. A boundary between adjacent measurement points where the orientation difference between the measurement points was more than 15° was defined as a high-angle grain boundary, and a length thereof was represented by L_{HB}. A ratio of the length of the low-angle grain boundary and the subgrain boundary to the length of all the grain boundaries, i.e., L_{LB}/(L_{LB}+L_{HB}) was obtained.

(Vickers Hardness)

Measurement by a method specified in JIS Z 2244 was performed on a sheet-thickness central portion in a surface perpendicular to the width direction of rolling of the obtained hot-rolled copper alloy sheet, that is, a transverse-direction (TD) surface.

(State of Tears During Milling Task)

Each specimen was formed into a flat plate of 100×2000 mm, and a surface thereof was cut at a cutting depth of 0.12 mm and at a cutting speed of 4500 m/min by a milling machine using a tool with a carbide edge tip. The number of tear flaws having a length of 120 μm or more was evaluated in a 500 μm-square visual field on the cut surface.

(Number of Times of Abnormal Discharge)

An integrated target including a backing plate part was produced from each specimen so that a target part had a diameter of 152 mm. The target was attached to a sputtering device, and until the ultimate vacuum pressure in a chamber reached 2×10⁻⁵ Pa or less, the chamber was evacuated. Next, with the use of a pure Ar gas as a sputtering gas, discharge was performed for 8 hours at a sputtering output of 2100 W by a direct current (DC) power supply while a sputtering gas atmospheric pressure was set to 1.0 Pa. The total number of times of abnormal discharge was counted by measuring the number of times of abnormal discharge occurring during the discharge using an arc counter attached to the power supply.

TABLE 1

| | Composition (mass %) | | | | |
|---|---|---|---|---|---|
| | Mg | Al | Ag | Fe | S |
| Invention Example 1 | 0.8 | 5.3 | 0.0100 | 0.0009 | 0.0018 |
| Invention Example 2 | 0.9 | 0.5 | 0.0001 | 0.0019 | 0.0017 |
| Invention Example 3 | 2.1 | 4.6 | 0.0002 | 0.0014 | 0.0022 |
| Invention Example 4 | 0.7 | 1.2 | 0.0056 | 0.0014 | 0.0015 |
| Invention Example 5 | 1.9 | 0.9 | 0.0050 | 0.0020 | 0.0020 |
| Invention Example 6 | 1.2 | 5.7 | 0.0038 | 0.0012 | 0.0025 |
| Invention Example 7 | 1.3 | 4.2 | 0.0046 | 0.0018 | 0.0028 |
| Invention Example 8 | 0.9 | 3.8 | 0.0020 | 0.0015 | 0.0013 |
| Invention Example 9 | 0.2 | 0.4 | 0.0003 | 0.0017 | 0.0024 |
| Invention Example 10 | 0.9 | 1.5 | 0.0013 | 0.0009 | 0.0010 |
| Invention Example 11 | 0.7 | 3.4 | 0.0008 | 0.0010 | 0.0011 |
| Invention Example 12 | 0.4 | 1.8 | 0.0002 | 0.0010 | 0.0016 |
| Invention Example 13 | 0.3 | 0.6 | 0.0016 | 0.0016 | 0.0030 |
| Invention Example 14 | 1.5 | 5.0 | 0.0079 | 0.0013 | 0.0019 |
| Invention Example 15 | 1.6 | 3.3 | 0.0098 | 0.0684 | 0.0291 |
| Invention Example 16 | 0.6 | 2.1 | 0.0033 | 0.0012 | 0.0022 |
| Invention Example 17 | 1.0 | 4.5 | 0.0023 | 0.0014 | 0.0027 |
| Comparative Example 1 | 0.1 | 0.8 | 0.0083 | 0.0018 | 0.0027 |
| Comparative Example 2 | 0.3 | 0.1 | 0.0019 | 0.0014 | 0.0025 |
| Comparative Example 3 | 0.8 | 1.9 | 0.0086 | 0.0013 | 0.0015 |
| Comparative Example 4 | 1.3 | 4.0 | 0.0062 | 0.0011 | 0.0022 |
| Comparative Example 5 | 0.7 | 3.8 | 0.0001 | 0.0018 | 0.0017 |
| Comparative Example 6 | 1.1 | 4.6 | 0.0054 | 0.0017 | 0.0016 |
| Comparative Example 7 | 2.0 | 5.2 | 0.0046 | 0.0016 | 0.0013 |
| Comparative Example 8 | 1.7 | 5.0 | 0.0069 | 0.0015 | 0.0026 |

TABLE 2

| | Hot Rolling Step | | | | | | |
|---|---|---|---|---|---|---|---|
| | Final Four Passes | | | | | | |
| | Starting | End | Rolling Ratio (%) | | | | Cooling |
| | Temperature | Temperature | First | Second | Third | Fourth | Rate |
| | (° C.) | (° C.) | Pass | Pass | Pass | Pass | (° C./min) |
| Invention Example 1 | 830 | 789 | 37 | 28 | 21 | 11 | 300 |
| Invention Example 2 | 751 | 709 | 38 | 24 | 19 | 13 | 269 |
| Invention Example 3 | 791 | 749 | 26 | 18 | 13 | 8 | 287 |
| Invention Example 4 | 822 | 770 | 44 | 34 | 21 | 15 | 274 |
| Invention Example 5 | 665 | 618 | 38 | 25 | 20 | 14 | 251 |
| Invention Example 6 | 619 | 568 | 25 | 18 | 14 | 5 | 221 |
| Invention Example 7 | 811 | 764 | 42 | 33 | 20 | 10 | 268 |
| Invention Example 8 | 700 | 655 | 38 | 23 | 17 | 12 | 253 |
| Invention Example 9 | 623 | 561 | 24 | 19 | 15 | 7 | 237 |
| Invention Example 10 | 723 | 687 | 23 | 21 | 19 | 17 | 254 |
| Invention Example 11 | 758 | 727 | 21 | 19 | 17 | 16 | 277 |
| Invention Example 12 | 833 | 786 | 40 | 32 | 25 | 13 | 291 |
| Invention Example 13 | 805 | 743 | 33 | 24 | 11 | 7 | 283 |
| Invention Example 14 | 711 | 669 | 24 | 20 | 13 | 6 | 259 |
| Invention Example 15 | 810 | 755 | 33 | 26 | 17 | 12 | 287 |
| Invention Example 16 | 771 | 736 | 35 | 30 | 24 | 19 | 179 |
| Invention Example 17 | 607 | 557 | 48 | 40 | 38 | 33 | 234 |
| Comparative Example 1 | 831 | 774 | 23 | 19 | 14 | 11 | 293 |
| Comparative Example 2 | 764 | 703 | 41 | 31 | 24 | 14 | 271 |
| Comparative Example 3 | 579 | 513 | 42 | 35 | 29 | 18 | 209 |
| Comparative Example 4 | 871 | 822 | 40 | 36 | 28 | 19 | 316 |
| Comparative Example 5 | 779 | 727 | 4 | 3 | 2 | 2 | 268 |
| Comparative Example 6 | 626 | 563 | 49 | 49 | 49 | 49 | 212 |
| Comparative Example 7 | 679 | 636 | 11 | 24 | 31 | 42 | 237 |
| Comparative Example 8 | 622 | 577 | 29 | 23 | 19 | 14 | 70 |

TABLE 3

| | Evaluation of Characteristics of Hot-Rolled Copper Alloy Sheet | | | | | | |
|---|---|---|---|---|---|---|---|
| | | Average | | | | | |
| | Cube | Crystal | Average | | | L_{LB}/(L_{LB} + | Vickers |
| | Orientation | Grain Size | KAM | σ/μ | Aspect | L_{HB}) | Hardness |
| | (%) | (μm) | value | (%) | Ratio | (%) | (HV) |
| Invention Example 1 | 1 | 36 | 0.8 | 48 | 0.3 | 3 | 63 |
| Invention Example 2 | 4 | 23 | 1.1 | 56 | 0.7 | 8 | 86 |
| Invention Example 3 | 3 | 27 | 1.0 | 52 | 0.7 | 3 | 82 |
| Invention Example 4 | 3 | 33 | 0.9 | 53 | 0.8 | 3 | 70 |
| Invention Example 5 | 3 | 14 | 1.3 | 62 | 0.6 | 5 | 105 |
| Invention Example 6 | 1 | 10 | 2.0 | 90 | 0.3 | 9 | 120 |
| Invention Example 7 | 2 | 30 | 0.8 | 55 | 0.4 | 4 | 58 |
| Invention Example 8 | 3 | 16 | 1.5 | 70 | 0.4 | 6 | 110 |
| Invention Example 9 | 5 | 11 | 1.8 | 80 | 0.3 | 7 | 114 |
| Invention Example 10 | 4 | 15 | 1.3 | 58 | 0.6 | 5 | 99 |
| Invention Example 11 | 1 | 18 | 1.0 | 53 | 0.6 | 4 | 90 |
| Invention Example 12 | 4 | 40 | 0.8 | 50 | 0.8 | 2 | 50 |
| Invention Example 13 | 5 | 25 | 1.0 | 51 | 0.6 | 3 | 84 |
| Invention Example 14 | 1 | 22 | 1.4 | 65 | 0.5 | 6 | 103 |
| Invention Example 15 | 2 | 31 | 1.0 | 51 | 0.7 | 4 | 84 |
| Invention Example 16 | 3 | 39 | 1.6 | 92 | 0.5 | 8 | 52 |
| Invention Example 17 | 4 | 9 | 1.9 | 74 | 0.2 | 11 | 123 |
| Comparative Example 1 | 4 | 44 | 0.9 | 51 | 0.8 | 3 | 73 |
| Comparative Example 2 | 8 | 38 | 1.1 | 58 | 0.7 | 4 | 80 |
| Comparative Example 3 | 4 | 9 | 3.1 | 78 | 0.1 | 23 | 126 |
| Comparative Example 4 | 1 | 66 | 1.0 | 45 | 0.7 | 4 | 78 |
| Comparative Example 5 | 11 | 56 | 0.9 | 56 | 0.8 | 2 | 73 |
| Comparative Example 6 | 1 | 10 | 2.6 | 77 | 0.2 | 17 | 128 |
| Comparative Example 7 | 1 | 14 | 2.8 | 70 | 0.2 | 18 | 136 |
| Comparative Example 8 | 3 | 83 | 1.7 | 94 | 0.4 | 9 | 110 |

TABLE 4

| | Evaluation | |
|---|---|---|
| | Surface | Number of Times |
| | State | of Abnormal |
| | (number | Discharge |
| | of tears) | (number) |
| Invention Example 1 | 0 | 1 |
| Invention Example 2 | 1 | 0 |
| Invention Example 3 | 1 | 2 |
| Invention Example 4 | 0 | 0 |
| Invention Example 5 | 1 | 0 |
| Invention Example 6 | 0 | 1 |
| Invention Example 7 | 0 | 1 |
| Invention Example 8 | 0 | 0 |
| Invention Example 9 | 2 | 3 |
| Invention Example 10 | 0 | 0 |
| Invention Example 11 | 0 | 0 |
| Invention Example 12 | 2 | 1 |
| Invention Example 13 | 1 | 2 |
| Invention Example 14 | 1 | 2 |
| Invention Example 15 | 4 | 6 |
| Invention Example 16 | 4 | 8 |
| Invention Example 17 | 3 | 7 |
| Comparative Example 1 | 10 | 32 |
| Comparative Example 2 | 9 | 34 |
| Comparative Example 3 | 6 | 27 |
| Comparative Example 4 | 11 | 35 |
| Comparative Example 5 | 11 | 31 |
| Comparative Example 6 | 6 | 29 |
| Comparative Example 7 | 7 | 28 |
| Comparative Example 8 | 13 | 42 |

In Comparative Example 1, the amount of Mg was less than the range of the present embodiment, and the average crystal grain size was 44 μm. In Comparative Example 1, the number of tears during cutting was large, and the number of times of abnormal discharge was large.

In Comparative Example 2, the amount of Al was less than the range of the present embodiment, and the area ratio of Cube orientation was 8%. In Comparative Example 2, the number of tears during cutting was large, and the number of times of abnormal discharge was large.

In Comparative Example 3, the starting temperature before the final four passes of hot rolling and the end temperature after the final four passes were low, and the average KAM value was 3.1. In Comparative Example 3, the number of tears during cutting was large, and the number of times of abnormal discharge was large.

In Comparative Example 4, the starting temperature before the final four passes of hot rolling and the end temperature after the final four passes were high, and the average crystal grain size was 66 μm. In Comparative Example 4, the number of tears during cutting was large, and the number of times of abnormal discharge was large.

In Comparative Example 5, the rolling ratio in each pass was reduced as the passes of hot rolling progressed, but the rolling ratio in three passes among the final four passes was low, the area ratio of Cube orientation was 11%, and the average crystal grain size was 56 μm. In Comparative Example 5, the number of tears during cutting was large, and the number of times of abnormal discharge was large.

In Comparative Example 6, the rolling ratio in the final four passes of hot rolling was high, the average KAM value was 2.6, and the aspect ratio was 0.2. In Comparative Example 6, the number of tears during cutting was large, and the number of times of abnormal discharge was large.

In Comparative Example 7, the rolling ratio in the latter pass of the final four passes of hot rolling was high, the average KAM value was 2.8, and the aspect ratio was 0.2. In Comparative Example 7, the number of tears during cutting was large, and the number of times of abnormal discharge was large.

In Comparative Example 8, the cooling rate after hot rolling was 70° C./min which was small, and the average crystal grain size was 83 μm. In Comparative Example 8, the number of tears during cutting was large, and the number of times of abnormal discharge was large.

In contrast, in Invention Examples 1 to 17, the amount of Mg, the amount of Al, the amount of Ag, the average KAM value, the area ratio of Cube orientation, and the average crystal grain size μ in the sheet-thickness central portion were within the ranges of the present embodiment. In Invention Examples 1 to 17, the number of tears during cutting was suppressed to 4 or less, and the number of occurrences of abnormal discharge was 8 or less.

From the results of the above Examples, it has been confirmed that according to Invention Examples, it is possible to provide a hot-rolled copper alloy sheet which has excellent cuttability and can sufficiently suppress abnormal discharge even in a case where the hot-rolled copper alloy sheet is used as a sputtering target, and a sputtering target.

### INDUSTRIAL APPLICABILITY

A hot-rolled copper alloy sheet according to the present embodiment is suitably used as a hot worked product such as a sputtering target, a backing plate, an electron tube for an accelerator, or a magnetron. A sputtering target according to the present embodiment is suitably used for depositing a copper alloy thin film for wiring.

1. A hot-rolled copper alloy sheet comprising:
0.2 mass % or more and 2.1 mass % or less of Mg;
0.4 mass % or more and 5.7 mass % or less of Al;
0.01 mass % or less of Ag; and
a remainder being Cu and inevitable impurities,
wherein a measurement area of 150000 μm² or more is measured at a measurement interval of 1 μm by an EBSD method, measurement results are analyzed by data analysis software OIM to obtain a CI value at each measurement point, measurement points where the CI value is 0.1 or less are removed, an orientation difference between crystal grains is analyzed, an area ratio of Cube orientation (area ratio of crystal orientation) in the measurement region is 5% or less, and an average kernel average misorientation (KAM) value when a boundary between adjacent pixels where an orientation difference between the pixels is 5° or more is regarded as a crystal grain boundary is 2.0 or less, and
an average crystal grain size μ in a sheet-thickness central portion is 40 μm or less.

2. The hot-rolled copper alloy sheet according to claim 1,
wherein a standard deviation a of crystal grain sizes in the sheet-thickness central portion is 90% or less of the average crystal grain size μ in the sheet-thickness central portion.

3. The hot-rolled copper alloy sheet according to claim 1,
wherein a measurement area of 150000 μm² or more is measured at a measurement interval of 1 μm by an EBSD method, measurement results are analyzed by data analysis software OIM to obtain a CI value at each measurement point, measurement points where the CI value is 0.1 or less are removed, an orientation difference between crystal grains is analyzed by the data analysis software OIM, a boundary between adjacent measurement points where an orientation difference between the measurement points is 15° or more is defined as a grain boundary, and an aspect ratio b/a expressed by a major diameter a and a minor diameter b of the crystal grain size (excluding twin crystals) is 0.3 or more.

4. The hot-rolled copper alloy sheet according to claim 1,
wherein a measurement area of 150000 μm² or more is measured at a measurement interval of 1 μm by an EBSD method, measurement results are analyzed by data analysis software OIM to obtain a CI value at each measurement point, measurement points where the CI value is 0.1 or less are removed, an orientation difference between crystal grains is analyzed by the data analysis software OIM, and when a length of a low-angle grain boundary and a subgrain boundary which are boundaries between adjacent measurement points where an orientation difference between the measurement points is 2° or more and 15° or less is represented by L_{LB}, and a length of a high-angle grain boundary which is a boundary between adjacent measurement points where an orientation difference between the measurement points is more than 15° is represented by L_{HB}, the following expression is satisfied,
L_{LB}/(L_{LB}+L_{HB})<10%.

5. The hot-rolled copper alloy sheet according to claim 1,
wherein a Vickers hardness is 120 HV or less.

6. The hot-rolled copper alloy sheet according to claim 1,
wherein among the inevitable impurities, an amount of Fe is 0.0020 mass % or less, and an amount of S is 0.0030 mass % or less.

7. A sputtering target comprising:
the hot-rolled copper alloy sheet according to claim 1.
